(19) United States
(12) Patent Application Publication
(10) Pub. No.: US 2026/0173317 A1
(43) Pub. Date: Jun. 18, 2026

(54) LIQUID COOLING SYSTEM FOR AN ELECTRONIC DEVICE

(71) Applicant: QUALCOMM Incorporated, San Diego, CA (US)

(72) Inventors: Shibsankar SARKAR, Hyderabad (IN); Manesh KALYADAPU, Hyderabad (IN); Madhu Babu DHORETI, Hyderabad (IN)

(21) Appl. No.: 18/985,708

(22) Filed: Dec. 18, 2024

(51) Int. Cl. H05K 7/20; G06F 1/20

(52) U.S. Cl. CPC H05K 7/20327; G06F 1/203; H05K 7/20154; H05K 7/20336; H05K 7/20381

(57) ABSTRACT

In an aspect, an electronic device includes an electronic component; a liquid cooling system configured to dissipate heat generated by the electronic component, the liquid cooling system comprising: a liquid cooling plate in contact with the electronic component; a radiator module; a micro-pump in line with the radiator module and the liquid cooling plate, wherein the micro-pump is configured to direct a flow of liquid coolant through the radiator module and the liquid cooling plate; and a centrifugal fan connected to the radiator module and configured to direct a flow of air to dissipate heat from the radiator module, wherein the liquid cooling plate, the radiator module, the micro-pump, and the centrifugal fan are disposed with respect to one another along a common plane.

### FIELD OF DISCLOSURE

The present disclosure generally relates to integrated circuit technology, and more particularly, to thermal dissipation of heat generated by an electronic component of the electronic device.

### BACKGROUND

Electronic products generate heat during operation due to electrical resistance and the high-density integration of components. It is important for such products to include effective cooling systems dissipate this heat and ensure the functionality, reliability, and longevity of these devices. Without proper thermal management, excessive heat can lead to performance degradation since heat affects the efficiency of semiconductors, reducing their performance and potentially causing thermal throttling in processors and graphics processing units. Additionally, prolonged exposure to high temperatures can degrade materials, damage sensitive components, and lead to early failure of critical parts. Still further, overheating may result in unexpected crashes, data loss, or malfunctions, severely impacting user experience and productivity.

As the size of electronic products is reduced, the heat density of heat generated by the components within such products becomes more concentrated. However, although the intensity may increase, the space available for effective cooling systems is reduced.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an electronic device includes an electronic component; a liquid cooling system configured to dissipate heat generated by the electronic component, the liquid cooling system comprising: a liquid cooling plate in contact with the electronic component; a radiator module; a micro-pump in line with the radiator module and the liquid cooling plate, wherein the micro-pump is configured to direct a flow of liquid coolant through the radiator module and the liquid cooling plate; and a centrifugal fan connected to the radiator module and configured to direct a flow of air to dissipate heat from the radiator module, wherein the liquid cooling plate, the radiator module, the micro-pump, and the centrifugal fan are disposed with respect to one another along a common plane.

In an aspect, a liquid cooling system includes a liquid cooling plate configured for contact with a heat-generating electronic component; a radiator module; a micro-pump in line with the radiator module and the liquid cooling plate, wherein the micro-pump is configured to direct a flow of liquid coolant through the radiator module and the liquid cooling plate; and a centrifugal fan connected to the radiator module and configured to direct a flow of air to dissipate heat from the radiator module, wherein the liquid cooling plate, the radiator module, the micro-pump, and the centrifugal fan are disposed with respect to one another along a common plane.

In an aspect, a liquid cooling system includes a liquid cooling plate configured for contact with an electronic component, the liquid cooling plate having an inlet and an outlet arranged to direct a flow of a liquid coolant through a chamber of the liquid cooling plate; a set of serpentine cooling pipes connected to the inlet and the outlet of the liquid cooling plate; a micro-pump in line with the set of serpentine cooling pipes and configured to direct a flow of the liquid coolant through the set of serpentine cooling pipes and the chamber of the liquid cooling plate, wherein the liquid cooling plate, the set of serpentine cooling pipes, and the micro-pump are arranged to direct the flow of the liquid coolant along a horizontal liquid flow path of the liquid cooling system; a fin stack at least partially surrounding the set of serpentine cooling pipes; and a centrifugal fan connected to the fin stack, wherein the centrifugal fan and the fin stack are arranged to direct a flow of air along a horizontal air flow path to dissipate heat from the set of serpentine cooling pipes.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure.

FIG. 1A through FIG. 1C illustrate an example laptop that may incorporate a liquid cooling system, according to aspects of the disclosure.

FIG. 2 is an exploded view of an example liquid cooling system, according to aspects of the disclosure.

FIGS. 3A and 3B show an example liquid cooling plate, according to aspects of the disclosure.

FIG. 4 shows an example of a liquid cooling system in an assembled state, according to aspects of the disclosure.

FIG. 5 shows an example of a dual-sided liquid cooling system as assembled in a base portion of a laptop computer, according to aspects of the disclosure.

FIG. 6 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC).

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to cooling systems used to dissipate heat generated by electronic components of a product. In some examples, the cooling system is a liquid cooling system that uses a liquid coolant to dissipate such heat. In some examples, the particular elements of the liquid cooling system and the configuration of those elements provide effective heat dissipation while concurrently reducing the liquid cooling system's size to a size compatible with the product in which it is incorporated. In an aspect, the liquid cooling system may be incorporated into the base of the slim laptop, where the system can effectively call the laptop components concentrated in such a slim design while fitting in the reduced real estate available in the slim laptop form factor.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. It will also be understood that when a layer is described as “over,” “overlying,” “under,” “underlying,” another layer does not necessarily preclude the use of intermediate layers and/or materials that may otherwise be used to ensure adhesion between the layers. Still further, it will be understood that when a layer is described as “over,” “overlying,” “under,” “underlying,” another layer that such terms are used with reference to the orientations of such layers as depicted in the reference frame shown in the corresponding figures.

Although the present disclosure discusses the liquid cooling system in the context of its use in a slim laptop computer, it will be recognized, based on the teachings of the disclosure, that the disclosed liquid cooling system may be used in any type of product, particularly those that have a high density of electronic components with limited space available for an effective cooling system.

Laptop cooling systems are needed to maintain the performance, stability, and longevity of portable computing devices. As laptops become more compact and powerful, their components, such as central processing units (CPU) and graphic processing units (GPU, generate significant heat during operation. Without effective cooling, this heat can lead to thermal throttling, where the system reduces performance to prevent overheating, impacting user experience and productivity. Additionally, sustained high temperatures can accelerate wear on components, reducing the lifespan of the device. Efficient cooling systems facilitate the laptop designs that balance compactness, power efficiency, and performance while ensuring the system operates within safe temperature ranges.

Traditional air-cooling systems, which have constituted the principal laptop thermal solutions, are becoming increasingly inadequate. The compact and slim designs of modern laptops leave limited space for traditional air-cooling solutions. As laptop designs become thinner and more powerful, the limitations of air cooling become more pronounced. Air cooling systems require considerable space for airflow channels and large fans, which can be difficult to accommodate within the form factor of the laptop computer without compromising other design aspects. This inefficiency is particularly problematic during intensive tasks such as gaming, video editing, and other demanding applications airflow.

Certain aspects of the disclosure are implemented with the recognition that air cooling is less efficient in transferring heat away from critical components compared to liquid cooling. However, conventional liquid cooling solutions have thus far been unable to fit within the available real estate of compact electronic products. Accordingly, aspects of the disclosure are directed to a liquid cooling system using an arrangement of compact cooling components that effectively dissipates the heat generated in products with a high density of heat-generating devices while meeting the size requirements for inclusion in the product.

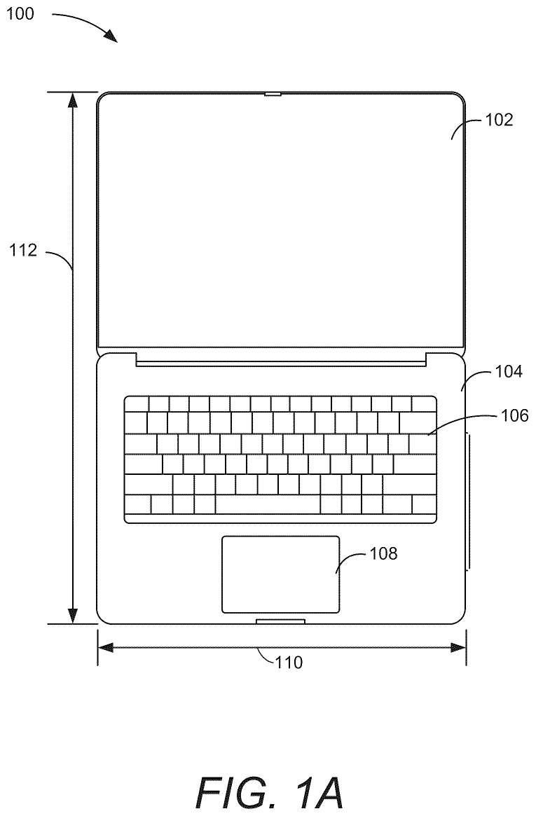

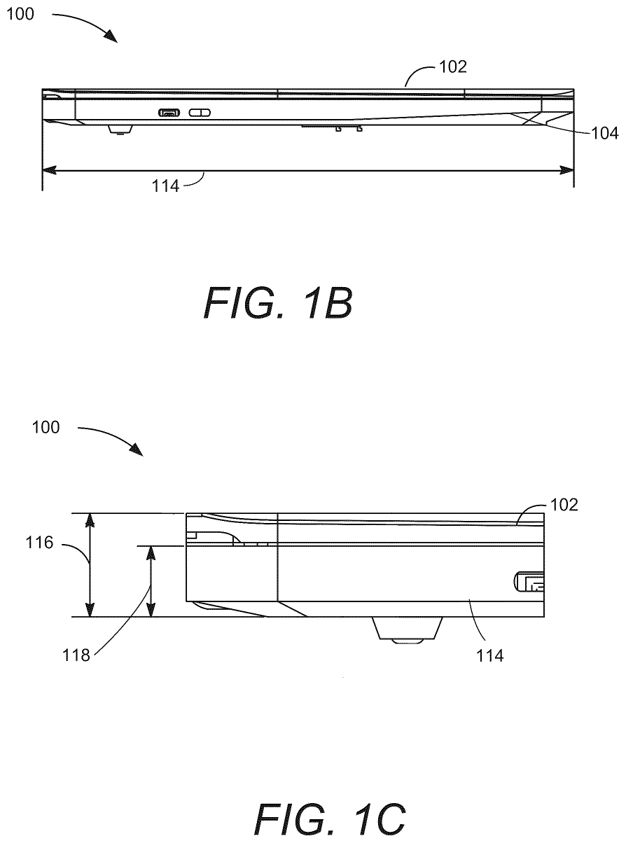

FIG. 1A through FIG. 1C illustrate an example laptop 100 that may incorporate a liquid cooling system, according to aspects of the disclosure. In FIG. 1A, the laptop 100 is shown in an open state having a display screen portion 102 and a base portion 104. In an aspect, a liquid cooling system constructed in accordance with certain aspects of the disclosure, may be incorporated in the base portion with a power supply, processing components, communication components, input-output components, etc. In this example, the base portion 104 may be bounded at its upper region by a keyboard 106, touchpad 108, etc. In an aspect, the example laptop 100 may have outside dimensions with a width 110 of about 335 millimeters and a total length 112 of about 482 millimeters when fully open.

FIG. 1B as a side view of the laptop 100 with the display screen portion 102 closed over the base portion 104, according to aspects of the disclosure. In this example, the base portion 104 may have a width 114 of about 245 millimeters.

FIG. 1C is a close-up side view of the laptop 100 with the display screen portion 102 closed over the base portion 104, according to aspects of the disclosure. In this example, the laptop 100 may have a total height 116 of about 16.9 millimeters when closed. In an aspect, the base portion 104 may have a height 118 of about 11.5 millimeters. As such, the enclosure for the base portion 104 shown in this example may have a width 110 of about 335 millimeters, a depth 115 of about 245 millimeters, and a height 118 of about 11.5 millimeters. As the need to increase the number of electronic components housed in the base portion 104 of a laptop 100 increases (e.g., to increase the functionality/performance), the space available for a cooling system in the base portion 104, without increasing the size of the base portion 104, decreases significantly.

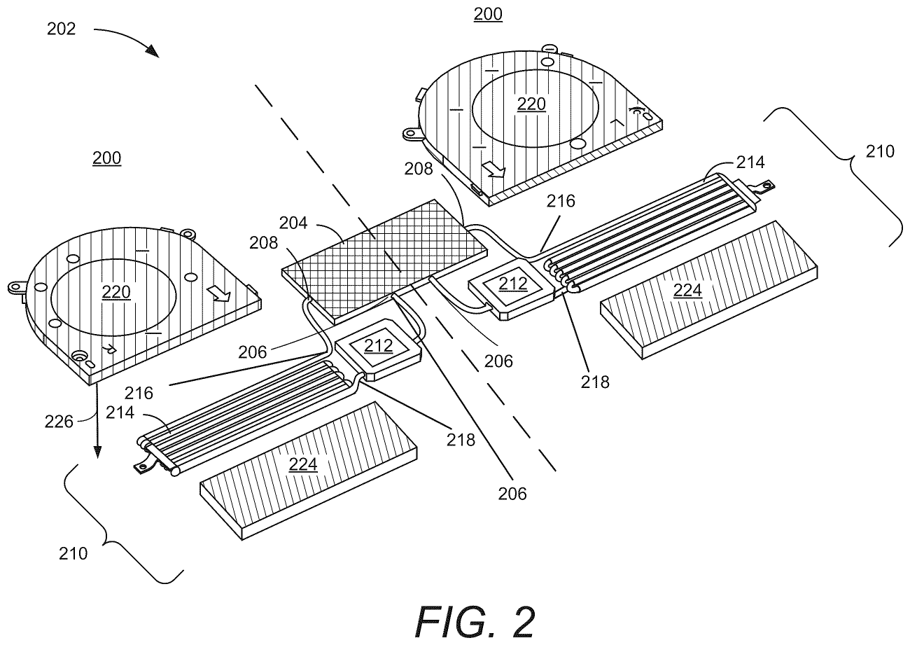

FIG. 2 is an exploded view of an example liquid cooling system 200, according to aspects of the disclosure. In this example, two liquid cooling systems 200 that are mirror images of one another are integrated into a dual-sided liquid cooling system 202. For purposes of the following discussion, only a single liquid cooling system 200 will be addressed.

In the example shown in FIG. 2, the liquid cooling system 200 includes a liquid cooling plate 204 that is configured for contact with an electronic component or other heat-generating portion of an electronic product. Here, the liquid cooling plate 204 includes at least one inlet port 206 (two shown in the mirrored systems of FIG. 2) and at least one outlet port 208 (two shown in the mirrored systems of FIG. 2) for passing the liquid coolant through the liquid cooling plate 204.

The interior of the liquid cooling plate 204 may be configured to facilitate heat transfer from the heat source (e.g., CPU, GPU, or other electronic components) to the liquid coolant as the liquid coolant flows through the liquid cooling plate 204. In an aspect, the liquid cooling plate 204 may include structures and features to optimize the flow of coolant and maximize thermal exchange. In an aspect, the liquid cooling plate 204 may include an outer shell having an interior chamber with flow channels and/or micro-channels (e.g., very small channels with a high surface-area-to-volume ratio for improved thermal performance) that provide pathways through which the liquid coolant may flow through the liquid cooling plate 204. In an aspect, the flow channels may be constructed to maximize contact between the coolant and the heat-conductive elements of the liquid cooling plate 204. In accordance with various aspects of the disclosure, the flow channels may be in the form of 1) straight channels, 2) serpentine channels, 3) zip fin channels, or a combination thereof. In an aspect, the interior of the liquid cooling plate 204 may include a manifold or plenum chambers that are configured to evenly distribute the liquid coolant across the flow channels and collect the fluid after the fluid has absorbed heat. In an aspect, the flow channels may have textured surfaces to increase the turbulence of the liquid coolant as it flows through the liquid cooling plate 204, thereby improving the efficiency of the heat exchange.

The liquid cooling plate 204 may be constructed from a metal or other material having a high thermal conductivity For example, liquid cooling plate 204 may be constructed from C1020 or C1100 copper having a thermal conductivity greater than about 350 watts per meter-kelvin (W/m-K). In accordance with certain aspects of the disclosure, all of the structures of the liquid cooling plate 204 need not be constructed from a single high thermal conductivity material but may include structures formed from different high thermal conductivity materials.

The liquid cooling system 200 shown in FIG. 2 also includes at least one radiator module 210 and at least one micro-pump 212. Here, the micro-pump 212 is in-line with the liquid cooling plate 204 and the radiator module 210 and drives the liquid coolant through both structures. As used herein, a “micro-pump” is a device designed to control and manipulate small fluid volumes, typically with functional dimensions in the micrometer range.

In an aspect, the micro-pump 212 may be in the form of a compact mechanical or electro-mechanical device designed to enhance heat management by circulating the liquid coolant through the heat absorption and heat dissipating portions of the liquid cooling system 200. Here, micro-pump 212 facilitates efficient heat dissipation by pumping the liquid coolant through the interior of the liquid cooling plate 204 (e.g., through microchannels), where the liquid coolant absorbs the heat from the attached heat-generating component(s) (e.g., CPUs, GPUs, systems on a chip (SOC), etc.), and therefrom, to the radiator module 210, where the heat absorbed by the liquid coolant is dissipated.

In FIG. 2, the micro-pump 212 is a piezoelectric micro-pump that uses piezoelectric actuators to move the liquid coolant. In an aspect, the micro-pump 212 may be disposed in a supporting structure or surrounded by a bezzle to provide ready access to its input and exit ports as it is assembled with other portions of the liquid cooling system 200. In an aspect, the micro-pump may have a width of 25 mm, depth of 4.8 mm, and a height of 25 mm.

It will be recognized that different types of micro-pumps (other than piezoelectric type pumps) may be used in the liquid cooling system 200 in various scenarios. Such different types of micro-pumps include, for example, electromagnetic micro-pumps (e.g., micro-pumps that use electromagnetic force to move the liquid coolant), centrifugal micro-pumps (e.g., micro-pumps that employ a small impeller to drive fluid flow), micro-electromechanical-based pumps (e.g., pumps based on micro-electromechanical system technology), etc.

According to various aspects of the disclosure, the radiator module 210 may be comprised of multiple structures. Here, the radiator module 210 includes a heat pipe structure 214 having a serpentine arrangement of heat pipes. In an aspect, the heat pipes of the heat pipe structure 214 may be comprised of 2.0 millimeter tubing made from a material having high-thermal conductivity (e.g., copper). The heat pipe structure 214 includes a fluid inlet 216 that receives liquid coolant from the liquid cooling plate 204 and a fluid outlet 218 that provides the liquid coolant exiting the heat pipe structure 214 to the inlet port of the micro-pump 212.

The radiator module 210 of the liquid cooling system 200 also includes a zipper fin cooling element 224. Here, the zipper fin cooling element 224 functions as a type of heat sink that absorbs heat from the heat pipe structure 214. In an aspect, the 224 fin cooling element may be constructed of interlocking or zippered individual fin elements that are attached to a base plate, creating a highly efficient and compact heat dissipation module. In an example, the zipper fin cooling element 224 may include thin, individually stamped or machined metal fins that are slid into grooves or slots on a base plate. Additionally, or in the alternative, the metal fins may be mechanically interlocked with one another. At least the fins of the zipper fin cooling element 224 may be constructed from a material having a high-thermal conductivity (e.g., copper).

The heat accumulating in the radiator module 210 may be dissipated by the airflow provided by a fan. In FIG. 2, a flow of air through the radiator module 210 is provided by a centrifugal fan 220. In this example, the centrifugal fan 220 draws air from an inlet port 222 and exhausts the air in a direction 226 perpendicular to the direction of its air intake.

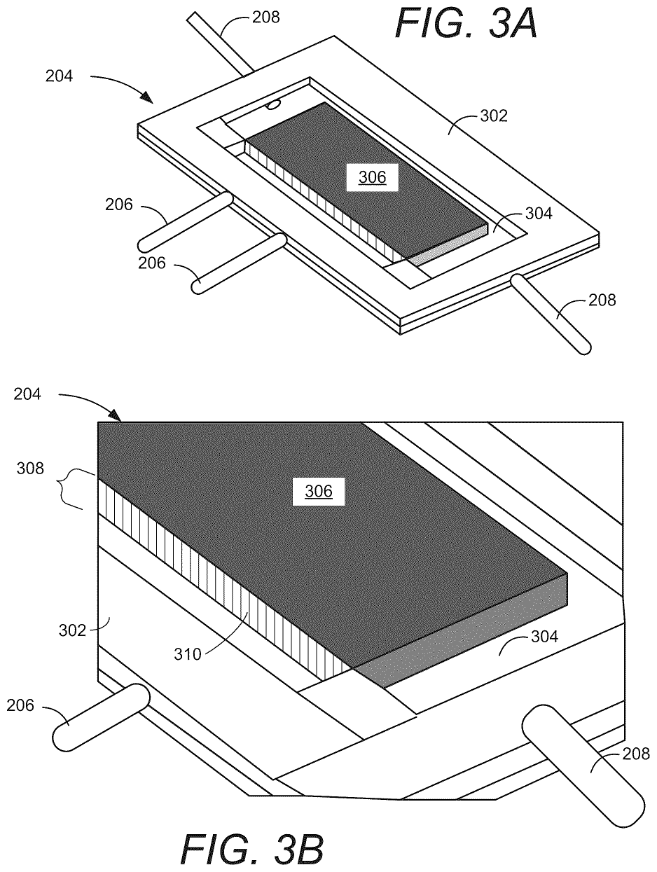

FIGS. 3A and 3B show an example liquid cooling plate, according to aspects of the disclosure. In this example, the liquid cooling plate 204 includes a shell 302 formed from a high thermal conductivity material (e.g., copper). The shell 302 includes chamber 304 at its interior that is configured to pass liquid coolant therethrough from inlet ports 206 to outlet ports 208. As the liquid coolant passes through the chamber 304 it also passes through a zipper fin element 306. In this example, the zipper fin element 306 includes zipper fins 308 in a pattern forming flow channels 310 through which the liquid coolant passes. Here, the liquid coolant is received at the inlet ports 206 after it has been cooled at the radiator module 210. The liquid coolant then flows into the chamber 304 and through the zipper fins 308 of the zipper fin element 306, where the liquid coolant absorbs the heat from a heat-generating electronic component (not shown) in contact with the shell 302. Heat transfer to the liquid coolant is enhanced by virtue of it passing through the zipper fin element 306. The heated liquid coolant thereafter passes to the outlet ports 208 and is pumped to the radiator module 210 where the liquid coolant is cooled.

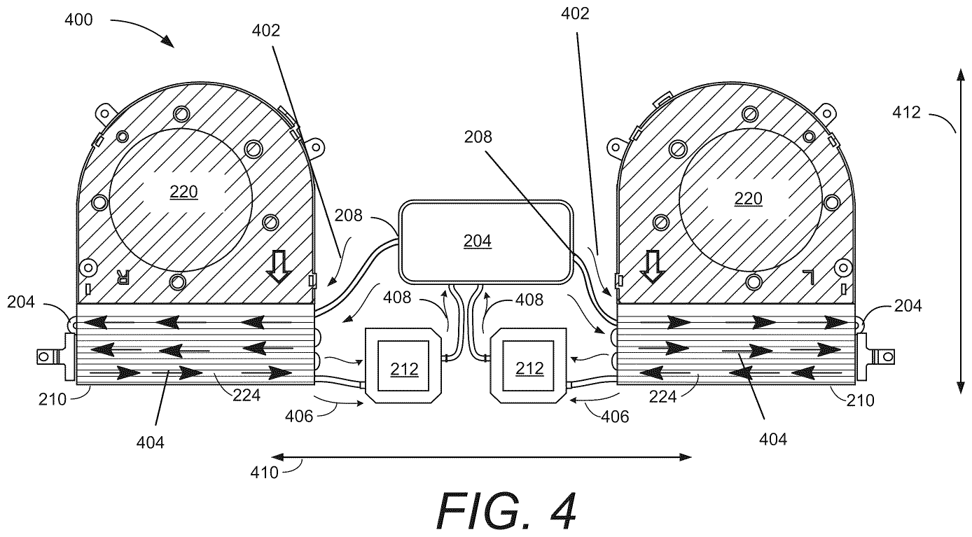

FIG. 4 shows an example of a liquid cooling system 400 in an assembled state, according to aspects of the disclosure. Here, the components of the radiator module 210 are assembled with one another. More particularly, the heat pipe structure 214 is secured with the zipper fin cooling element 224. In an aspect, the heat pipe structure 214 may be secured with the zipper fin cooling element 224 so that it is at least partially surrounded by the fins of the zipper fin cooling element 224. In an aspect, the assembled liquid cooling systems 400 may have an overall length of 220 mm, a width of 100 mm, and a height of 7 mm.

The transfer of heat through the liquid cooling system 400 may be described with respect to the assembled liquid cooling system 400 shown in FIG. 4. In this example, the liquid cooling plate 204 is placed in contact with the surface of a heat-generating component. The liquid coolant flowing through the liquid cooling plate 204 absorbs the heat from the heat-generating component and is expelled at the outlet port 208 of the liquid cooling plate 204. As such, the liquid coolant flowing along the flow path designated by arrows 402 has been heated through absorption of the heat from the heat-generating component. The heated liquid coolant enters the radiator module 210 and flows through the heat pipe structure 214, as indicated by arrows 404. In turn, the heated liquid coolant in the zipper fin cooling element 224 transfers the heat from the liquid coolant to the zipper fin cooling element 224. At this point, the centrifugal fan 220 generates an airflow through the zipper fin cooling element 224 to dissipate the heat absorbed by the zipper fin cooling element 224 and exhausts the heated air from the liquid cooling system.

Once the liquid coolant has been cooled in the radiator module 210, the proceeds to the input of the micro-pump 212, as indicated by arrows 406. The micro-pump 212 drives the cooled liquid coolant to the input of the liquid cooling plate 204, as indicated by arrows 408, where the heat absorption and heat dissipation cycle is repeated.

In an aspect, the liquid cooling plate, the radiator module, the micro-pump, and the centrifugal fan are disposed with respect to one another along a common horizontal plane to reduce the height of the liquid cooling system. As such, the liquid coolant proceeds along a horizontal liquid flow path designated by arrow 410. The flow of air generated by the centrifugal fans 220 flows along a horizontal airflow path designated by arrow 412, which is perpendicular to the horizontal liquid flow path designated by arrow 410.

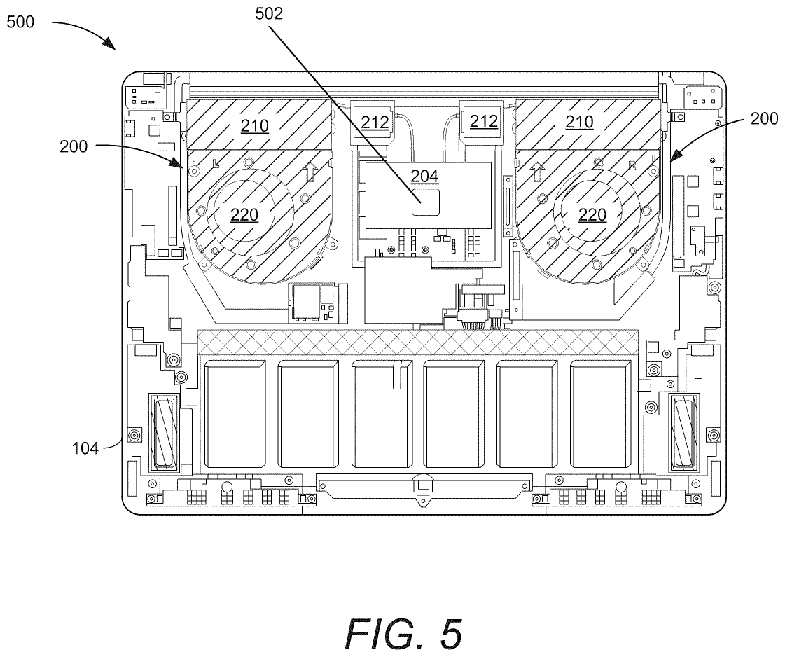

FIG. 5 shows an example of a dual-sided liquid cooling system 500 as assembled in a base portion 104 of a laptop computer, according to aspects of the disclosure. In this example, the liquid cooling plate 204 is placed in contact with a heat-generating component 502 (e.g., processor, SOC, etc.) so as to absorb the heat generated by the heat-generating component 502. The heat generated by the heat-generating component is absorbed and dissipated in accordance with the cycling of the liquid coolant depicted in FIG. 4.

In an aspect, the liquid cooling system 200 may include a thermal management controller. The thermal management controller may be configured to monitor the temperature of the liquid cooling plate 204 and adjust the speeds of the centrifugal fan 220 and micro-pump 212 to regulate the temperature at a proper level while minimizing the noise generated by these components.

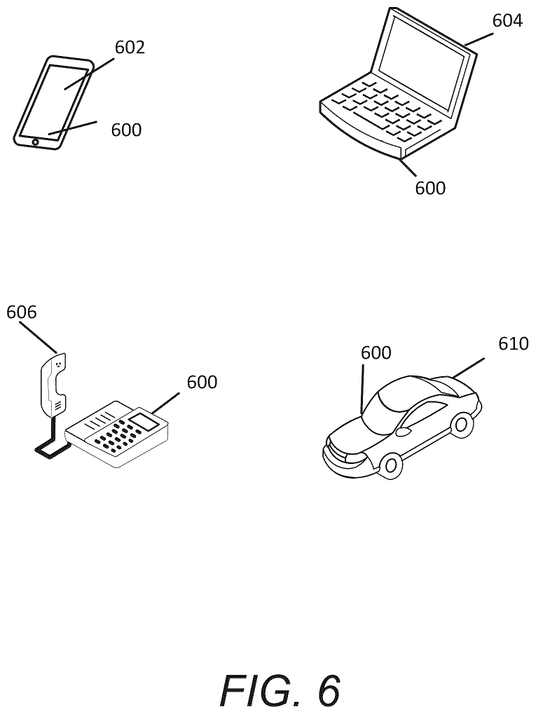

FIG. 6 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 602, a laptop computer device 604, a fixed location terminal device 606, or an automotive vehicle 610 may include a device 600 as described herein. The device 600 may be, for example, any of the devices described herein. The devices 602, 604, 608 and the vehicle 610 illustrated in FIG. 6 are merely exemplary. Other electronic devices may also feature the liquid cooling system 200 including, but not limited to, a group of devices (e.g., electronic devices) that includes mobile devices, hand-held personal communication systems (PCS) units, portable data units such as personal digital assistants, global positioning system (GPS) enabled devices, navigation devices, set-top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:

Aspect 1. An electronic device, comprising: an electronic component; a liquid cooling system configured to dissipate heat generated by the electronic component, the liquid cooling system comprising: a liquid cooling plate in contact with the electronic component; a radiator module; a micro-pump in line with the radiator module and the liquid cooling plate, wherein the micro-pump is configured to direct a flow of liquid coolant through the radiator module and the liquid cooling plate; and a centrifugal fan connected to the radiator module and configured to direct a flow of air to dissipate heat from the radiator module, wherein the liquid cooling plate, the radiator module, the micro-pump, and the centrifugal fan are disposed with respect to one another along a common plane.

Aspect 2. The electronic device of aspect 1, wherein: the radiator module comprises a serpentine arrangement of heat pipes in fluid communication with an inlet and an outlet of the liquid cooling plate; and a zipper fin cooling element at least partially surrounding the serpentine arrangement of heat pipes.

Aspect 3. The electronic device of aspect 2, wherein: the zipper fin cooling element is formed from a metal having a thermal conductivity equal to or greater than 350 watts per meter-kelvin.

Aspect 4. The electronic device of any of aspects 1 to 3, wherein: the liquid cooling plate is formed from a metal having a thermal conductivity equal to or greater than 380 watts per meter-kelvin.

Aspect 5. The electronic device of any of aspects 1 to 4, further comprising: a thermal management controller connected to the micro-pump for controlling the flow of the liquid coolant, and the centrifugal fan to control the flow of the air.

Aspect 6. The electronic device of any of aspects 1 to 5, wherein: the micro-pump is a piezoelectric micro-pump.

Aspect 7. The electronic device of any of aspects 1 to 6, wherein: the electronic component comprises a processor.

Aspect 8. The electronic device of any of aspects 1 to 6, wherein: the electronic component comprises a system-on-a-chip.

Aspect 9. The electronic device of any of aspects 1 to 8, wherein the liquid cooling system further comprises: a further radiator module; a further micro-pump in line with the further radiator module and the liquid cooling plate, wherein the micro-pump is configured to direct a further flow of liquid coolant through the further radiator module and the liquid cooling plate; and a further centrifugal fan connected to the further radiator module and configured to direct a flow of air to dissipate heat from the further radiator module, wherein the liquid cooling plate, the further radiator module, the further micro-pump, and the centrifugal fan are disposed with respect to one another along the common plane.

Aspect 10. The electronic device of any of aspects 1 to 9, wherein the electronic device further comprises: a laptop computer having a base portion underlying a keyboard; and wherein the liquid cooling system is enclosed within the base portion.

Aspect 11. A liquid cooling system, comprising: a liquid cooling plate in configured for contact with a heat-generating electronic component; a radiator module; a micro-pump in line with the radiator module and the liquid cooling plate, wherein the micro-pump is configured to direct a flow of liquid coolant through the radiator module and the liquid cooling plate; and a centrifugal fan connected to the radiator module and configured to direct a flow of air to dissipate heat from the radiator module, wherein the liquid cooling plate, the radiator module, the micro-pump, and the centrifugal fan are disposed with respect to one another along a common plane.

Aspect 12. The liquid cooling system of aspect 11, wherein: the radiator module comprises a serpentine arrangement of heat pipes in fluid communication with an inlet and an outlet of the liquid cooling plate; and a zipper fin cooling element at least partially surrounding the serpentine arrangement of heat pipes.

Aspect 13. The liquid cooling system of aspect 12, wherein: the zipper fin cooling element is formed from a metal having a thermal conductivity equal to or greater than 350 watts per meter-kelvin.

Aspect 14. The liquid cooling system of any of aspects 11 to 13, wherein: the liquid cooling plate is formed from a metal having a thermal conductivity equal to or greater than 380 watts per meter-kelvin.

Aspect 15. The liquid cooling system of any of aspects 11 to 14, further comprising: a thermal management controller connected to the micro-pump for controlling the flow of the liquid coolant, and the centrifugal fan to control the flow of the air.

Aspect 16. The liquid cooling system of any of aspects 11 to 15, wherein: the micro-pump is a piezoelectric micro-pump.

Aspect 17. The liquid cooling system of any of aspects 11 to 16, wherein: the heat-generating electronic component comprises a processor.

Aspect 18. The liquid cooling system of any of aspects 11 to 16, wherein: the heat-generating electronic component comprises a system-on-a-chip.

Aspect 19. A liquid cooling system, comprising: a liquid cooling plate configured for contact with an electronic component, the liquid cooling plate having an inlet and an outlet arranged to direct a flow of a liquid coolant through a chamber of the liquid cooling plate; a serpentine arrangement of heat pipes connected to the inlet and the outlet of the liquid cooling plate; a micro-pump in line with the serpentine arrangement of heat pipes and configured to direct a flow of the liquid coolant through the serpentine arrangement of heat pipes and the chamber of the liquid cooling plate, wherein the liquid cooling plate, the serpentine arrangement of heat pipes, and the micro-pump are arranged to direct the flow of the liquid coolant along a horizontal liquid flow path of the liquid cooling system; a fin stack at least partially surrounding the set of serpentine cooling pipes; and a centrifugal fan connected to the fin stack, wherein the centrifugal fan and the fin stack are arranged to direct a flow of air along a horizontal air flow path to dissipate heat from the set of serpentine cooling pipes.

Aspect 20. The liquid cooling system of aspect 19, wherein: the micro-pump is a piezoelectric micro-pump.

It is noted that the figures in the disclosure may represent actual representations and/or conceptual representations of various parts, components, objects, devices, packages, integrated devices, integrated circuits, and/or transistors. In some instances, the figures may not be to scale. In some instances, for the purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on the bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect(s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An electronic device, comprising:
an electronic component;
a liquid cooling system configured to dissipate heat generated by the electronic component, the liquid cooling system comprising:
a liquid cooling plate in contact with the electronic component;
a radiator module;
a micro-pump in line with the radiator module and the liquid cooling plate, wherein the micro-pump is configured to direct a flow of liquid coolant through the radiator module and the liquid cooling plate; and
a centrifugal fan connected to the radiator module and configured to direct a flow of air to dissipate heat from the radiator module, wherein
the liquid cooling plate,
the radiator module,
the micro-pump, and
the centrifugal fan are disposed with respect to one another along a common plane.

2. The electronic device of claim 1, wherein:
the radiator module comprises
a serpentine arrangement of heat pipes in fluid communication with an inlet and an outlet of the liquid cooling plate; and
a zipper fin cooling element at least partially surrounding the serpentine arrangement of heat pipes.

3. The electronic device of claim 2, wherein:
the zipper fin cooling element is formed from a metal having a thermal conductivity equal to or greater than 350 watts per meter-kelvin.

4. The electronic device of claim 1, wherein:
the liquid cooling plate is formed from a metal having a thermal conductivity equal to or greater than 380 watts per meter-kelvin.

5. The electronic device of claim 1, further comprising:
a thermal management controller connected to
the micro-pump for controlling the flow of the liquid coolant, and
the centrifugal fan to control the flow of the air.

6. The electronic device of claim 1, wherein:
the micro-pump is a piezoelectric micro-pump.

7. The electronic device of claim 1, wherein:
the electronic component comprises a processor.

8. The electronic device of claim 1, wherein:
the electronic component comprises a system-on-a-chip.

9. The electronic device of claim 1, wherein the liquid cooling system further comprises:
a further radiator module;
a further micro-pump in line with the further radiator module and the liquid cooling plate, wherein the micro-pump is configured to direct a further flow of liquid coolant through the further radiator module and the liquid cooling plate; and
a further centrifugal fan connected to the further radiator module and configured to direct a flow of air to dissipate heat from the further radiator module, wherein
the liquid cooling plate,
the further radiator module,
the further micro-pump, and
the centrifugal fan are disposed with respect to one another along the common plane.

10. The electronic device of claim 1, wherein the electronic device further comprises:
a laptop computer having a base portion underlying a keyboard; and
wherein the liquid cooling system is enclosed within the base portion.

11. A liquid cooling system, comprising:
a liquid cooling plate in configured for contact with a heat-generating electronic component;
a radiator module;
a micro-pump in line with the radiator module and the liquid cooling plate, wherein the micro-pump is configured to direct a flow of liquid coolant through the radiator module and the liquid cooling plate; and
a centrifugal fan connected to the radiator module and configured to direct a flow of air to dissipate heat from the radiator module, wherein
the liquid cooling plate,
the radiator module,
the micro-pump, and
the centrifugal fan are disposed with respect to one another along a common plane.

12. The liquid cooling system of claim 11, wherein:
the radiator module comprises
a serpentine arrangement of heat pipes in fluid communication with an inlet and an outlet of the liquid cooling plate; and
a zipper fin cooling element at least partially surrounding the serpentine arrangement of heat pipes.

13. The liquid cooling system of claim 12, wherein:
the zipper fin cooling element is formed from a metal having a thermal conductivity equal to or greater than 350 watts per meter-kelvin.

14. The liquid cooling system of claim 11, wherein:
the liquid cooling plate is formed from a metal having a thermal conductivity equal to or greater than 380 watts per meter-kelvin.

15. The liquid cooling system of claim 11, further comprising:
a thermal management controller connected to
the micro-pump for controlling the flow of the liquid coolant, and
the centrifugal fan to control the flow of the air.

16. The liquid cooling system of claim 11, wherein:
the micro-pump is a piezoelectric micro-pump.

17. The liquid cooling system of claim 11, wherein:
the heat-generating electronic component comprises a processor.

18. The liquid cooling system of claim 11, wherein:
the heat-generating electronic component comprises a system-on-a-chip.

19. A liquid cooling system, comprising:
a liquid cooling plate configured for contact with an electronic component, the liquid cooling plate having an inlet and an outlet arranged to direct a flow of a liquid coolant through a chamber of the liquid cooling plate;
a serpentine arrangement of heat pipes connected to the inlet and the outlet of the liquid cooling plate;
a micro-pump in line with the serpentine arrangement of heat pipes and configured to direct a flow of the liquid coolant through the serpentine arrangement of heat pipes and the chamber of the liquid cooling plate, wherein the liquid cooling plate, the serpentine arrangement of heat pipes, and the micro-pump are arranged to direct the flow of the liquid coolant along a horizontal liquid flow path of the liquid cooling system;
a fin stack at least partially surrounding the serpentine arrangement of heat pipes; and
a centrifugal fan connected to the fin stack, wherein the centrifugal fan and the fin stack are arranged to direct a flow of air along a horizontal air flow path to dissipate heat from the serpentine arrangement of heat pipes.

20. The liquid cooling system of claim 19, wherein:
the micro-pump is a piezoelectric micro-pump.
